(19) United States
(12) Patent Application Publication
(10) Pub. No.: US 2016/0184988 A1
(43) Pub. Date: Jun. 30, 2016

(54) Vibration Sensor

(71) Applicant: Sigenic Pte Ltd, Singapore (SG)

(72) Inventors: Koh Min Zhuan, Singapore (SG); Eugene Chong Wui Chyun, Singapore (SG)

(21) Appl. No.: 14/974,844

(22) Filed: Dec. 18, 2015

(30) Foreign Application Priority Data
Dec. 26, 2014 (SG) 10201408730Q
Feb. 13, 2015 (SG) 10201501132Q

(51) Int. Cl. B25J 9/16; G01H 11/06; H01L 21/687; G01H 17/00

(52) U.S. Cl. CPC B25J 9/161; G01H 17/00; G01H 11/06; B25J 9/1694; B25J 9/1628; H01L 21/68707; Y10S 901/09

(57) ABSTRACT

A handling device has a robot arm, the arm having a vibration sensor and a coupling device. The vibration sensor is mounted on the arm, and the coupling device is configured to conductively connect the vibration sensor to processing circuitry located remotely therefrom. A second handling device has a robot arm, the arm having a vibration sensor and a coupling device. The vibration sensor is mounted on the arm, and the coupling device is configured to connect the vibration sensor to power supply circuitry located remotely therefrom. A robot arm vibration sensor has coupling device for connecting the sensor to power and control circuitry. The coupling device is configured to allow the power and control circuitry to be disposed remotely from the sensor.

### CROSS-REFERENCE TO RELATED APPLICATIONS

This application claims priority under 35 U.S.C. §119 or 365 to Singapore Patent Application No. 10201408730Q, filed Dec. 26, 2014. This application also claims priority under 35 U.S.C. §119 or 365 to Singapore Patent Application No. 10201501132Q, filed Feb. 13, 2015. The entire teachings of the above applications are incorporated herein by reference.

### FIELD OF THE INVENTION

The present invention relates to the field of mechanical handling. More particularly, the invention relates to a handling device having a robot arm. The invention also relates to a robot arm vibration sensor.

Embodiments relate to robots for handling semiconductor wafers, photo masks, optical disks, magnetic discs and the like. Applications include Factory Interface (FI) robots and buffer robots. The invention is however not restricted to any particular application.

### BACKGROUND

Taking the example of fabricating semiconductor devices, in mass production systems it is necessary to move semiconductor wafers between processing stations and, in some systems, to move the semiconductor wafers into and out of cassettes. These functions are generally performed by robotic arms in which the arm engages with a semiconductor wafer and moves the wafer from a first position to the second position, or moves the wafer into a cassette or moves the wafer from inside a cassette to outside the cassette.

The wafer is relatively fragile and somewhat easily damaged.

It is necessary for the robotic arm to be accurately controlled and aligned to avoid damage to wafers. If either the alignment or the control of the robotic arm is incorrect, it may be possible for the robotic arm to crash into or to scrape over the wafer and damage it. It is also possible for a wafer-cassette to become damaged or misaligned either due to a previous collision with the arm or with another robotic arm or due to another cause. If the cassette has been damaged or misaligned it may have parts that interfere with the correct movement of the robot arm and indeed the robot arm may collide with or scrape over a part of the cassette. If these collisions or damages occur, they may allow detritus to cause further problems

Previous attempts to address this situation have involved disposing a sensor on the robotic arm. One approach has been to use a vibration sensor mounted, together with its control and power circuitry, on the arm. An example of a sensor is InvenSense MPU-6050, which is a MEMS integrated 6-axis motion tracking device that combines a 3-axis gyroscope, 3-axis accelerometer, and a processor in an IC package. The control circuitry is operated to cause the vibration sensor to monitor the movement of and the robotic arm and to provide some form of output to inhibit continued operation of the robot arm or to provide a warning to an operator of the system.

The prior art devices can solve the problem to a certain extent, but place undesirable constraints upon the system as a whole. The size and weight of the robotic arm is undesirable increased′.

Increasing the size of the arm to accommodate the vibration sensor, its power supplies, and its control circuitry is contrary to the constraints of making the robotic arm as small as possible so as to interfere as little as possible with other components of the fabrication system. Increasing the weight of the arm by mounting on it the vibration sensor, its power supplies and its control circuitry increases the mass of the arm and affects the vibration frequency of the arm in an undesirable way. Thirdly the conditions at the engagement end of the robotic arm are often hostile, for example potentially the environment has widely varying temperature conditions that can place difficult constraints upon the operation of the control and driving circuitry for the vibration sensor. Alternatively there are systems in which the robot arm may contact liquids or reactive gases, in which case the sensor may need to be sealed. One way of doing this is to mount the sensor inside the arm; however there is insufficient space to dispose the power and control electronics at the same location.

It is widely believed that the vibration sensor must be proximate the power and control circuitry which is the reason why these latter components are mounted on the arm close to the vibration sensor itself. However it has been discovered by the present inventors that the power and control circuitry can be mounted a sufficient distance from the vibration sensor that the power and control circuitry is no longer required to be mounted on the robotic arm.

In other embodiments the inventors have interposed a repeater device between the vibration sensor and the control circuitry, the repeater device typically receiving signals from the vibration sensor in a local-type protocol such as SPI or I²C, and converting to a transmission protocol

### SUMMARY OF THE INVENTION

The invention is defined in the independent claims. Some optional features of the invention are defined in the dependent claims.

In one arrangement there is provided a robot arm having a vibration sensor mounted thereon, the vibration sensor being communicatively coupled with a controller located remotely therefrom.

A repeater may be interposed between the vibration sensor and the controller.

The repeater may be configured to receive signals from the vibration sensor and to convey information derived from those signals to the processing circuitry

The repeater may comprise power supply circuitry for the vibration sensor, the vibration sensor having a ground node and the repeater providing a connection to ensure the ground potential at the vibration sensor is that at the location of the processing circuitry

In another arrangement there is provided a robot arm having a vibration sensor mounted thereon, the robot arm being communicatively coupled with a controller via a cable

In a third arrangement there is provided a robot arm having a vibration sensor mounted thereon, the vibration sensor head having a power connection and a cable connecting the power connection to a remote voltage regulator.

In a fourth arrangement there is provided a robot arm having a vibration sensor mounted thereon, the vibration sensor head having a power connection and a cable connecting the power connection to a remote voltage regulator and connecting the vibration sensor to a controller wherein the controller and vibration sensor are configured to communicate using I²C.

There may be four conductors connecting the vibration sensor to the controller and/or voltage regulator.

There may be a ground conductor connecting a ground terminal of the vibration sensor to a ground of the controller or respectively regulator

In a further arrangement there is provided a handling device having a robot arm, the arm having a vibration sensor and a coupling device, the vibration sensor being mounted on the arm, and the coupling device configured to connect the vibration sensor to processing circuitry located remotely therefrom.

The vibration sensor may have power connection nodes, the coupling device being configured to connect the power connection nodes to power supply circuitry local to the processing circuitry

The vibration sensor may have a ground node and the coupling device provide a connection to ensure the ground potential at the vibration sensor is that at the location of the processing circuitry

In yet a further arrangement there is provided a handling device having a robot arm, the arm having a vibration sensor and a coupling device, the vibration sensor being mounted on the arm, and the coupling device configured to connect the vibration sensor to power supply circuitry located remotely therefrom.

The coupling device may be configured to connect the vibration sensor to processing circuitry located locally to the power supply circuitry.

The processing circuitry may be configured to convert I²C signals from the vibration sensor into PWM signals. It may convert I²C signals from the vibration sensor into other signals as required by the robot circuitry. It may comprise a DAC to provide analog signals.

Where the vibration sensor does not provide I²C signals, the processing circuitry may perform other transformations as needed.

One other specific example is where the vibration sensor outputs SPI signals.

The coupling device may comprise a screened cable.

The vibration sensor may have a ground node and the coupling device provide a connection to ensure the ground potential at the vibration sensor is that at the location of the processing circuitry. The location remote from the vibration sensor may be a location on a fixed part of the handling device.

The robot arm may be adapted to engage a semiconductor wafer.

The vibration sensor may be connected to the controller, or respectively processing circuitry, via ohmic connections but in some embodiments part or all of the linking between them is wireless, for example using infrared or radio frequencies.

Protocol conversion may be used between the vibration sensor and the controller, respectively processing circuitry.

There is also provided a robot arm vibration sensor having coupling device for connecting the sensor to power and control circuitry, the coupling device being configured to allow the power and control circuitry to be disposed remotely from the sensor.

The coupling device may be configured to allow the power and control circuitry to be secured on a non-moving part of the robot. The coupling device may comprise one or more cables

### BRIEF DESCRIPTION OF THE DRAWINGS

FIG. 1 shows a highly schematic view of a part of a wafer processing system to which the invention may be applied

FIG. 2 shows a schematic drawing of a part of a wafer processing system embodying the invention

FIG. 3 shows a schematic drawing of a part of another wafer processing system embodying the invention

FIG. 4 shows a schematic drawing of a part of yet another wafer processing system embodying the invention

### DESCRIPTION OF EMBODIMENTS

In the figures, like reference numerals refer to like parts

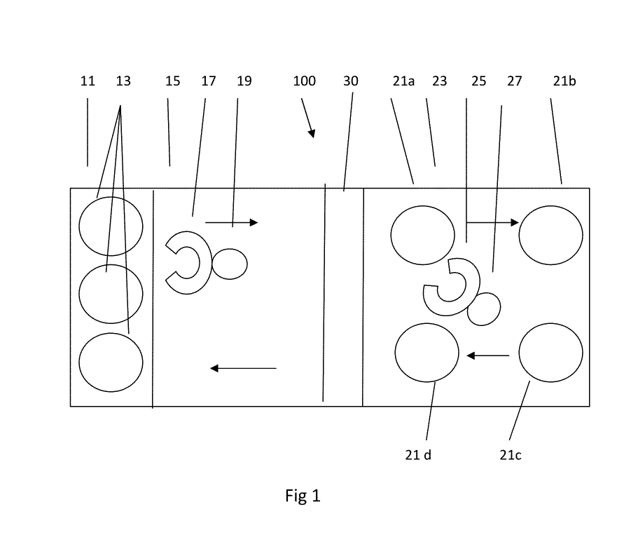

Referring to FIG. 1, a system 100 is shown with three locations, 11, 15 and 23. Location 11 is a storage location where three wafer cartridges 13 are waiting to be moved for processing. Location 15 is an unloading/loading location having a first robot 17 with an arm and a drive/control unit 19. Location 23 is a processing location for moving wafers, for between different processing stations and is illustrated as having a second robot 25 with an arm and a driver/control unit 27. There is a transit station 30 between locations 15 and 23.

At the loading/unloading location 15 wafers are unloaded from cassettes 13, for example FOUP cassettes by the robot arm 17 which is operated to pick up a wafer from a cassette at the storage location 13 and move it to the transit station 30. Wafers that have been processed will be waiting at the transit station 30, and are picked up by the robot 17 and brought back to the storage location 11 for loading into cassettes. It will be understood that the cassette unloading and loading functions may be performed by more than on robot and may be in different physical locations. The transit station 30 maybe sealable so that location 15 may be atmospheric whereas location 23 may be under vacuum.

At the processing location 23, for example a vacuum cluster, there are shown in this embodiment four processing stations 21a,b,c,d. The robot 25, under drive and control from its drive control unit 27 takes a first wafer from the transit station 30 and moves it to the first processing station 21a, then later picks up the processed wafer from that first station 21a and transfer it to the second processing station 21b and so on until processing is complete. It will be understood that the robot 25 may have plural arms, depending for example on the number of processing stations and other constraints. A fully processed wafer is returned to the transit station 30 for eventual pickup and return to cassettes.

In some embodiments the system operates in pipeline fashion, with a number of robot arms each moving respective wafers sequentially through the stations.

The arrangement shown is purely illustrative and the invention is not restricted to this or any other type of system. Other types of robots, for example robots allowing temporary storage of wafers, or allowing other types of processing are envisaged. The invention is, in any event, not restricted to semiconductor wafer processing 23.

As noted above, in each case where the robot arm is required to engage a wafer there are possible problems since the arm may have become misaligned or the wafer may be in an incorrect and unexpected position. Additionally or alternatively, arm movement may experience motion inconsistency and/or undesirable shaking, resulting in pick up failure, wafer drop or wafer damage. Failure to be able to react quickly to a problem of these types can cause serious difficulties.

The previously-mentioned solution has been to mount a vibration sensor together with its control and signalling circuitry on the arm. The InvenSense 6000 family of sensors are one example of such a vibration sensor, with a preferred device being the MPU6050. This sensor can be set up to measure vibration motions and transfer digital signals using the I²C protocol to a signal processor which is programmed to convert the digital signals into suitable signals for the drive/control units 19, 27. One suitable signal type is PWM signalling. Typically the signal processor is not powerful enough to drive a signal line directly, and so line drivers are used, for example operational amplifiers, to drive the signal lines to the drive/control unit.

The vibration sensor is operated from a regulated power supply, for example a 3.3 v supply suitable for operating the I²C protocol.

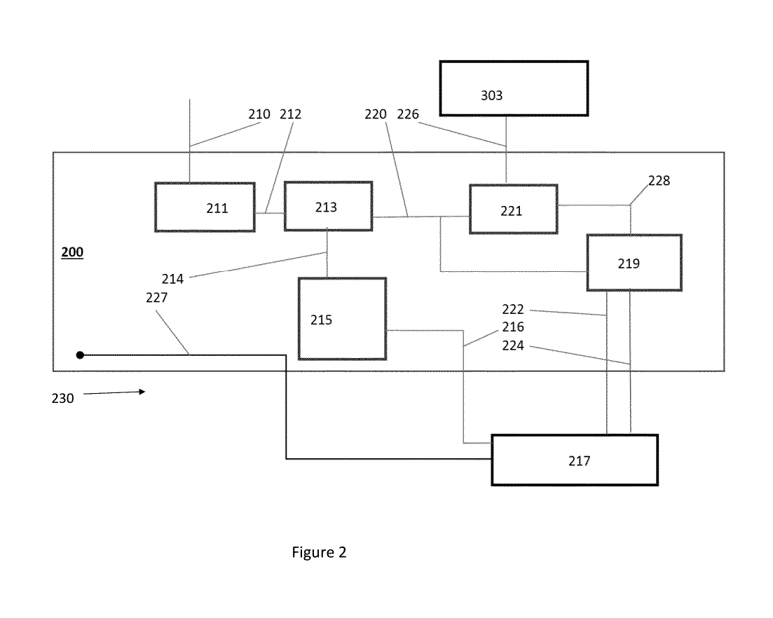

FIG. 2 shows a wafer processing system 230 having a robot arm, power and processing circuitry 200 and a robot drive and control device 303. The robot arm carries a vibration sensor 217 disposed at the portion of the arm that engages the wafer, or inside the arm, at that point or as close to that point as possible. However the power and processing circuitry, (hereinafter referred to as a board, for convenience only) 200 is not mounted at this location. The circuitry in this embodiment is not mounted on the arm but is remote from the arm, for example being disposed on the fixed structure of the robot, for example, 1.8 m away.

The power and processing board 200 has an input power line 210 connected to a filter 211. The filter 211 has a power output line 212 connected to a first voltage regulator 213 which has a first output 220 to line drivers 221 and a processing circuit 219. The first voltage regulator 213 has a voltage output 214 to a second voltage regulator 215, which in turn has a second voltage output 216. The second voltage output 216 is connected off the board 200 via a cable to a vibration sensor 217, in this embodiment an MPU6050.

In this embodiment, the processor 219 is an ATMega328.

The vibration sensor 217 has a first output 222 for the internally-generated serial clock and a second output 224 for serial data output from the internal circuitry of the vibration sensor. These are provided by cable back from the robot arm to the board 200. It also has a ground connection 227, again via cable back to ground on the board 200.

In one embodiment a single cable acts as a coupling device carrying voltage output 216, ground connection 227 and clock 222 and data 224 signals. In other embodiments more than one cable is used. For example a first cable may carry voltage output 216 and ground 227 connections and a second cable may carry the clock signal 222 and data signal 224

The serial clock 222 and serial data lines 224 are inputs to the processing circuit 219, which has an output 228 forming the input to the line drivers 221. In turn the line drivers 221 have an output connection 226 to the control device 303 of the robot.

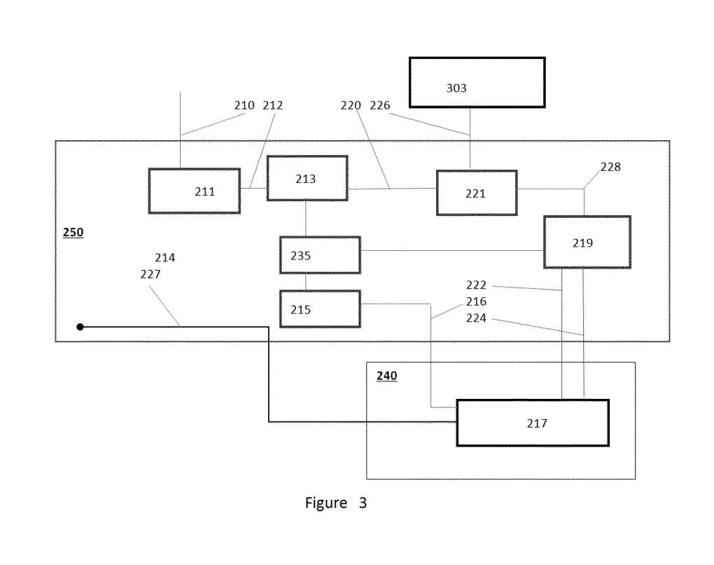

In operation the input line is typically 12 or 24 volts and the filter 211 is provided as a differential filter to avoid common mode voltages and other noise being input to the board 200. The first regulator 213 provides 5 volt output to the line drivers 221, the processing circuit 219 and the second regulator 215. The second regulator 215 provides a 3.3 v output to the vibration sensor. It will be understood that the specific voltage levels are not essential to the invention—for example higher voltages may be provided to the line drivers, which could for example be operational amplifiers, see FIG. 3.

The vibration sensor 217 provides I²C signals over the SDA 224 and SCL 222 lines to the signal processor 219, at the internal clock rate of the vibration sensor itself, these signals being representative or indicative of vibrations being sensed. It will be understood that in other embodiments external clocking may be used instead of the internal clocking. With some vibration sensors no internal clocking is provided in which case external clocking is required. The ground connection 227 is required to connect the vibration sensor 217 to the ground potential of the signal processor 219 so that I²C protocol signalling can take place. Without a common ground potential it would be possible for a potential difference to exist between the head of the robot arm, where the vibration sensor is mounted and the controller board, which may be for example 1.2-2.0 metres distant. It is noted that I²C signalling requires three lines, one ground line, a serial data and a serial clock line.

The processor 219 converts the I²C signals, for example register signals in the case of MPU6050, into a suitable form for consumption by the robot drive/controller 303.

In one embodiment this suitable form is PWM. However other forms of signalling are used in different variants.

In some embodiments the processor 219 is also programmed to send commands to the sensor 217 over the I²C connection to initiate measurements and the return of readings. When a measurement starts, the relevant readings are stored in the corresponding register of the sensor 217; and the processor 219 subsequently reads back the digital values from the corresponding register before converting to the vibration readings (analog, PWM) and outputting to the line drivers 221 for transfer to the external machine 303, for example, for comparing with a default threshold.

If the threshold is exceeded, a halt signal may be sent to the robot and/or an alarm may be sounded.

In other embodiments the vibration sensor 217 can respond to vibration by initiating a warning signal.

The cable can be a screened or shielded cable to reduce EMI interference from the machine operation. The sensor head is usually not more than 1.2m from the installation of the controller board but has been found to work up to at least 2 m.

In some embodiments, a compass function is added to detect the orientation of the robot arm. This uses one or more magnetometers installed in the sensor head. This is particularly beneficial when used in a buffer robot, to determine which direction the movement is in when vibration is detected.

In some embodiments an acoustic chip is incorporated and programmed such that the sensor head can also detect impending faults based on the acoustic signals (10-20 kHz) it receives.

In some embodiments, optical fibre is incorporated to the sides of the sensor head to act as a safety device for the operating robot. It can be configured such that light reflecting from the optic fibre can be used to proximity of the sensor head to an object. Thus, upon coming into close contact, the optical fibre will alert the system, and signals an emergency halt for the entire robot.

A second arrangement shown in FIG. 3 has a power and control board 250 with three voltage regulators in series, respectively first regulator 213 providing an output of 11 volts for line driver operational amplifiers 221, second voltage regulator 235 providing 5 volts for the processor 219 and third voltage regulator 215 providing 3.3 volts for the sensor head 217. This arrangement allows the use of LDO (low-dropout) components.

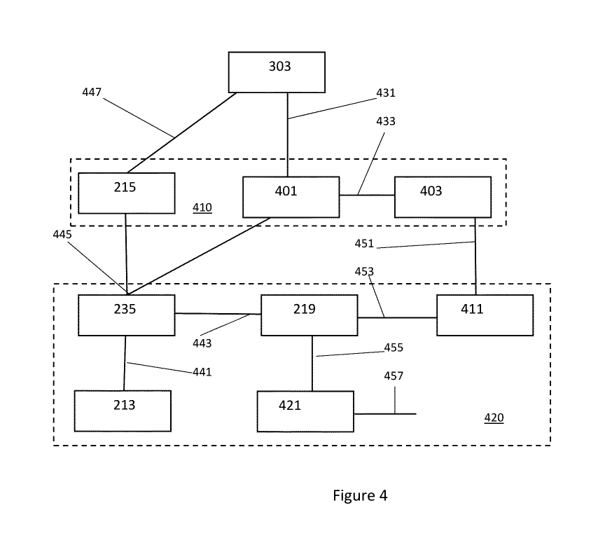

Referring now to FIG. 4, a third class of embodiments incorporates a repeater 410. The repeater 410 in the variant shown has a protocol converter 401 connected to receive signals from the vibration sensor 303 over a line 431. As protocol converter a microcontroller device, suitably programmed, may be used, or a proprietary IC may be used, as convenient. The repeater 410 also includes a level shifter 403 connected via a line 433 to receive signals output from the protocol converter 401, and the second voltage regulator 215 for converting a 5 v input over a line from output node 445 of the further voltage regulator 235 to the 3.3 volts needed for this vibration sensor 303 over a line 447. If other sensors with different needs are used, the second voltage regulator 215 is configured accordingly to provide the required supply level,

The first voltage regulator 213 has an output line 441 to the further voltage regulator 235.

The level shifter 403 provides a boosted signal to one end of a line 451, whose other end is coupled to a second level shifter 411 located in a controller 420. The stepped down signal from the second level shifter 411 is output via a connection 453 to a microcontroller 219, powered in this variant with 5 v from the further voltage regulator 235 over a line 443. The output of the microcontroller 219 is passed to analog output circuitry 421 via line 455 for output over a line 457 to alarms or indicators as necessary.

In use the I²C signals from the vibration sensor 303 are received by the protocol converter 401 and in one variant they are converted to an RS232 protocol signal. This signal is passed to the booster level shifter 403 and then the voltage-boosted RS232 signals are sent over the line 451 to the controller. The line 451 may be long for example up to 1.2 km is feasible. This allows the controller to be remote from the robot arm, and this in turn means that a single controller 420 may be able to handle many robots at a central location.

The repeater 410 may be mounted off the robot arm in some embodiments, or it may be on the arm but remote from the vibration sensor. In some embodiments where the repeater 410 is small and lightweight it may be close to or adjacent the vibration sensor 303.

Power to the booster level shifter 403, in some embodiments, is from an external +/−15 volt supply. In a more preferred embodiment, devices similar to TI SN65C3222 are used, such devices having an on-chip charge pump providing +15 volt and −15 volt from a single 3-5 volt supply. Similar options are used for the second level shifter 411.

Although I²C are used in the described embodiment, other signal protocols such as for example SPI may be used where the vibration sensors supports this. Equally although RS232 is quoted above, other protocols may be used on the line 451. The line 451 need not provide serial communication but may afford parallel communications.

Examples of such other protocols used in embodiments are RS-485, RS-422, CAN bus, SPI bus, USB bus, RS-232 by wire.

Instead of line 451, all or part of the line may be replaced by a wireless link. In one family of embodiments light or infrared is used to provide this link. In others, electrical links are used for example Bluetooth, WiFi, ZigBee.

Other arrangements use parallel regulators but may have disadvantages since parallel regulators will occupy more space. Serial connections of regulators can allow the use of smaller smoothing capacitors.

Due to the design requirements three different power supplies may be advantageous in some environments as they serve different purposes. Take 11 volts DC as an example, a signal voltage from 0V to +10 volts can be provided to overcome signalling issues caused by the electrically-noisy environment. Likewise a +5 volt dc is needed as the selected microcontroller 219 uses 5 volts.

In yet other embodiments, one, more or all of the regulators are replaced by a dc-dc converter or converters. Such devices tend to allow higher efficiency and lower power consumption. However special measures may be needed to avoid noise and interference caused for example by the clocking rate of the converter Operational amplifiers may be advantageous as line drivers. First, they can be configured to serve as a buffer between input and output terminal, and prevent loading of the input side. Secondly the operational amplifiers can serve as a two times voltage gain stage. A 5 volt supply means the processing circuit 219 can only have at most a 5 volt output swing. The output voltage swing of 10 volts to allow for noise (as discussed above), requires this gain.

The above description is based around the MPU6000 series sensor. However the invention is not restricted to this family and other accelerometers may be used with, in some cases, modification to the processing and other circuitry. Embodiments may use for example ADXL345, MPU9150.

The described embodiments may operate in various ways. One embodiment is operated in a training phase to determine the amount of vibration, for example the amount with a test wafer and the variation of vibration as the robot arm moves. This profile may be stored, or information indicative of the amount of vibration may be stored and used in determining a threshold or a threshold characteristic. Then during operation, while wafers are being produced, the threshold or threshold characteristic may be used to determine whether a current level of vibration is indicative of a fault. The training phase may be repeated from time to time, and variations from the originally-stored data may be used to indicate a need for maintenance.

The link 226 is shown as a conductive link. However all or some of this link may use other transmission means—for example optical signalling, inductive transmission or radio transmission may be used as at least part of that link.

Embodiments of the invention have now been described. The scope of the invention is not restricted to the described features but extends at least to the full scope of the appended claims.

1. A handling device having a robot arm, the arm having a vibration sensor and a coupling device, the vibration sensor being mounted on the arm, and the coupling device configured to conductively connect the vibration sensor to processing circuitry located remotely therefrom.

2. A handling device according to claim 1 in which the processing circuitry is configured to convert I²C signals from the vibration sensor into PWM signals.

3. A handling device according to claim 1 wherein the vibration sensor has power connection nodes, the coupling device configured to connect the power connection nodes to power supply circuitry local to the processing circuitry.

4. A handling device according to claim 1, further having a repeater configured to receive signals from the vibration sensor and to convey information derived from those signals to the processing circuitry.

5. A handling device according to claim 4, wherein the repeater comprises power supply circuitry for the vibration sensor, the vibration sensor having a ground node and the repeater providing a connection to ensure the ground potential at the vibration sensor is that at the location of the processing circuitry.

6. A handling device according to claim 1 in which the vibration sensor has a ground node and the coupling device provides a connection to ensure the ground potential at the vibration sensor is that at the location of the processing circuitry.

7. A handling device having a robot arm, the arm having a vibration sensor and a coupling device, the vibration sensor being mounted on the arm, and the coupling device configured to connect the vibration sensor to power supply circuitry located remotely therefrom.

8. A handling device according to claim 7 in which the coupling device is configured to connect the vibration sensor to processing circuitry located locally to the power supply circuitry.

9. A handling device according to claim 7 in which the processing circuitry is configured to convert I²C signals from the vibration sensor into PWM signals.

10. A handling device according to claim 7 in which the processing circuitry comprises a DAC to convert I²C signals from the vibration sensor into analog signals.

11. A handling device according to claim 1 wherein the coupling device comprises a screened cable.

12. A handling device according to claim 8 in which the vibration sensor has a ground node and the coupling device provides a connection to ensure the ground potential at the vibration sensor is that at the location of the processing circuitry.

13. A handling device according to claim 1 where the location remote from the vibration sensor is a location on a fixed part of the handling device.

14. A handling device according to claim 1 wherein the robot arm is adapted to engage a semiconductor wafer.

15. A robot arm vibration sensor having a coupling device for connecting the sensor to power and control circuitry, the coupling device being configured to allow the power and control circuitry to be disposed remotely from the sensor.

16. A robot arm vibration sensor according to claim 15, wherein the coupling device is configured to allow the power and control circuitry to be disposed on a non-moving part of the robot.

17. A robot arm vibration sensor according to claim 15 wherein the coupling device comprises at least one cable.
